(19) United States
(12) Patent Application Publication
(10) Pub. No.: US 2011/0086468 A1
(43) Pub. Date: Apr. 14, 2011

(54) ASSEMBLY OF SEMICONDUCTOR CHIPS/WAFERS

(76) Inventors: Yacine Felk, Grenoble (FR); Hamed Chaabouni, Grenoble (FR); Alexis Farcy, La Ravoire (FR)

(21) Appl. No.: 12/898,028

(22) Filed: Oct. 5, 2010

(30) Foreign Application Priority Data
Oct. 8, 2009 (FR) 09/57044
Oct. 1, 2010 (EP) 10185173.1

(51) Int. Cl. H01L 21/50

(52) U.S. Cl. 438/109; 257/E21.499

(57) ABSTRACT

A method for assembling a first semiconductor chip provided with pads on a second semiconductor chip or wafer provided with pads, comprising covering the chip(s) with a dielectric, superposing the two chips, the pads being arranged substantially opposite to each other, and applying a voltage difference between the pads of the first and second chips to cause a breakdown of the dielectric and a diffusion of the conductor forming the pads into the broken down areas, whereby a conductive path forms between the opposite pads.

### BACKGROUND OF THE INVENTION

1. Field of the Invention

The present invention relates to a semiconductor chip/wafer assembly process.

2. Discussion of the Related Art

To increase the compactness of electronic circuits, a tendency is to superpose semiconductor chips directly connected to one another to form what is currently called a three-dimensional (3D) integration. In this assembly, the chips of one and/or the other of the assembled levels may be parts of a same wafer.

FIG. 1A schematically shows an integrated circuit chip formed from a semiconductor substrate 1 currently silicon, having an upper layer 2 containing active components, for example, CMOS components. The active components are coated with an upper portion 3 comprising a large number of interconnect levels separated by insulating layers and especially intended to provide connections between regions of the components formed in layer 2 and contact pads 5.

As illustrated in FIG. 1B, to enable a face-to-face assembly of integrated circuit chips or of integrated circuit chips on an integrated circuit wafer, a known method is to electrolytically form on each of the pads a pillar 7, currently made of copper, on which is arranged a cap made of a solder material 9, for example, SnAg.

As illustrated in FIG. 1C, on a first wafer or chip P1 provided with pillars such as those of FIG. 1B, is placed a chip P2 provided with similar pillars so that the solder caps are opposite to one another. Then, a heating is performed to melt the solder caps and have them resolidify to attach chip P2 to chip P1.

At a next step, illustrated in FIG. 1D, the gap between the two chips or between the chip and the wafer is filled with a resin 11.

The above-described assembly process is particularly delicate to implement since, with currently available devices, it is difficult to bring chip P2 above chip P1 with an accuracy greater than ±10 μm. This process is thus prone to misalignments, designated with reference D in FIG. 2. Further, there is a risk for air bubbles 13 remaining when resin is injected, especially in the case where the pillar density is significant and/or the diameter of the pillars is large as compared with their density. Thus, this assembly process, even though it could be implemented satisfactorily, has significant shortcomings as to the maximum decrease of the dimensions that can be obtained, both as concerns the diameter of the pillars and their spacing.

### SUMMARY OF THE INVENTION

A purpose of an embodiment of the present invention is to provide an assembly of integrated circuit chips and/or chips and wafers enabling to obtain a high density of connections between chips.

Another purpose of an embodiment of the present invention is to provide such a structure avoiding misalignments.

To achieve the desired result, an embodiment of the present invention provides a method for assembling a first semiconductor chip provided with pads on a second semiconductor chip or wafer also provided with pads, comprising covering the chip(s) with a dielectric, superposing the two chips, the pads being arranged substantially opposed to one another, and applying a voltage difference between the pads of the first and second chips to cause a breakdown of the dielectric and a diffusion of the conductor forming the pads into the broken down areas, whereby a conductive path forms between the opposite pads.

According to an embodiment of the present invention, the pads are made of copper.

According to an embodiment of the present invention, the dielectric is SiO₂.

The foregoing features, and benefits of the present invention will be discussed in detail in the following non-limiting description of specific embodiments in connection with the accompanying drawings.

### BRIEF DESCRIPTION OF THE DRAWINGS

FIGS. 1A to 1D are cross-section views illustrating successive chip assembly steps;

FIG. 2 is a cross-section view illustrating a chip assembly;

FIGS. 3A to 3D are cross-section views illustrating successive steps of chip assembly according to an embodiment of the present invention; and

FIGS. 4 and 5 are cross-section views illustrating alternative chip assemblies according to an embodiment of the present invention.

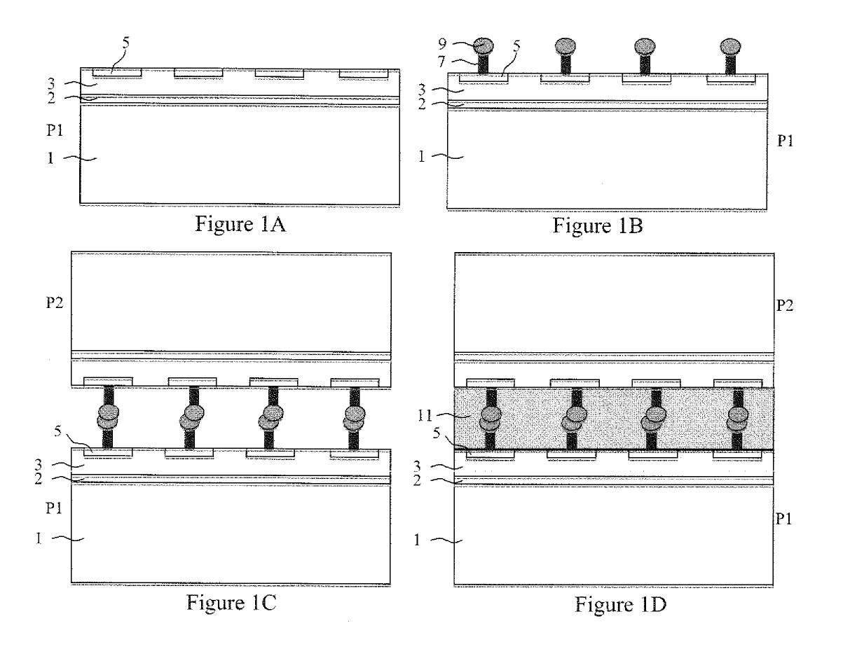

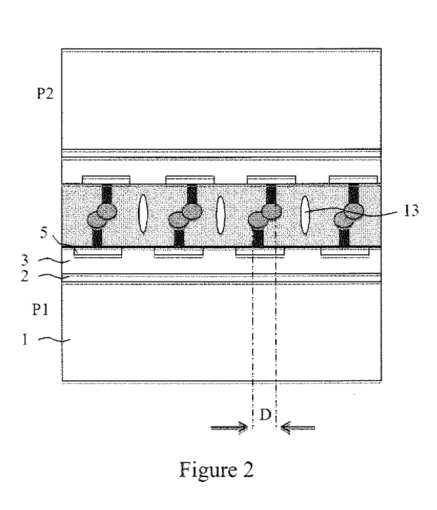

### DETAILED DESCRIPTION

For clarity, the same elements have been designated with the same reference numerals in the different drawings and, further, as usual in the representation of integrated circuits, the various drawings are not to scale.

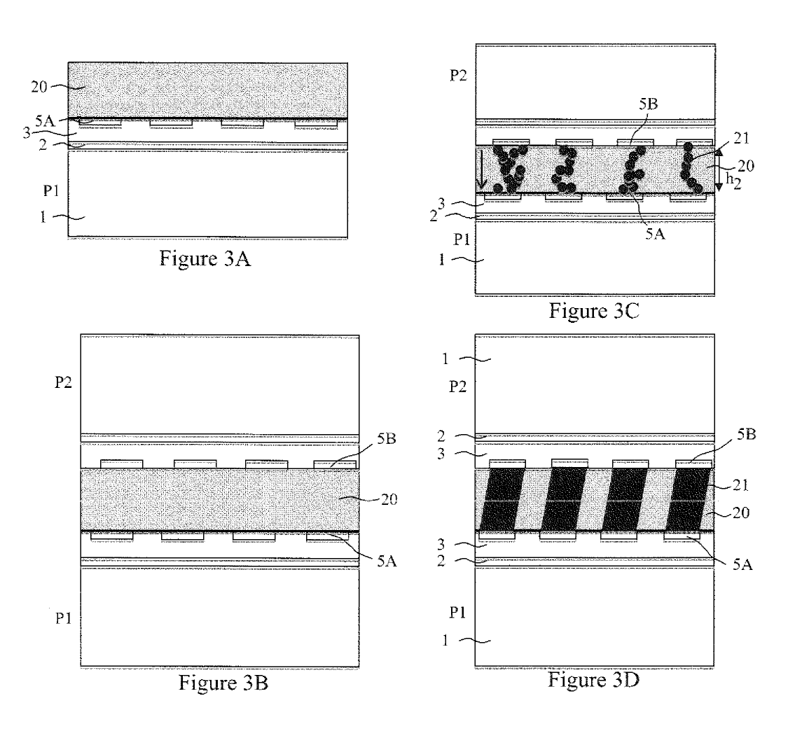

FIG. 3A shows an integrated circuit chip or wafer P1 according to an embodiment of the present invention. As previously, this chip comprises on a semiconductor substrate, currently a silicon substrate 1, an area 2, currently an epitaxial layer, in which components are formed, and an interconnect stack 3 on top of which are formed pads 5A. A layer of a dielectric 20, for example, SiO₂ or SiOCH, is formed on this assembly.

Then, as shown in FIG. 3B, a chip P2, similar to chip or wafer P1, is placed above chip P1, so that pads 5B of chip P2 are in front of pads 5A of chip P1, with as good an alignment as possible.

Then, a voltage difference is applied between the pads of chips P1 and P2. As a result, if the dielectric layer is sufficiently thin for the applied voltage, the dielectric breaks down and the metal of the pads, for example, copper, diffuses into it. This operation lasts for a very short time, for example, from 1 to 10 ms.

Conductive areas 21 between upper pads 5B and lower pads 5A are obtained, as shown in FIGS. 3C and 3D.

The disadvantages of currently known devices are thus avoided, that is, there can be no air bubbles in the dielectric separating the wafer or the lower chip from the upper chip, and possible misalignments of the contacts are compensated for.

As a variation, after the step illustrated in FIG. 3A, one may, for example, by immersion of the upper portion of the dielectric in a conductive liquid and by application of a voltage between the chip pads and the conductive liquid, form breakdown areas in which the pad conductor, and/or conductive atoms contained in the conductive solution, diffuse to provide a result similar to that shown in FIG. 3D, in which the dielectric layer comprises conductive areas. The upper chip is then installed. This variation of the present invention, although it does not compensate for possible misalignments in the positioning of the upper chip on the lower chip, at least avoids the generation of air bubbles in the intermediary dielectric between the two chips.

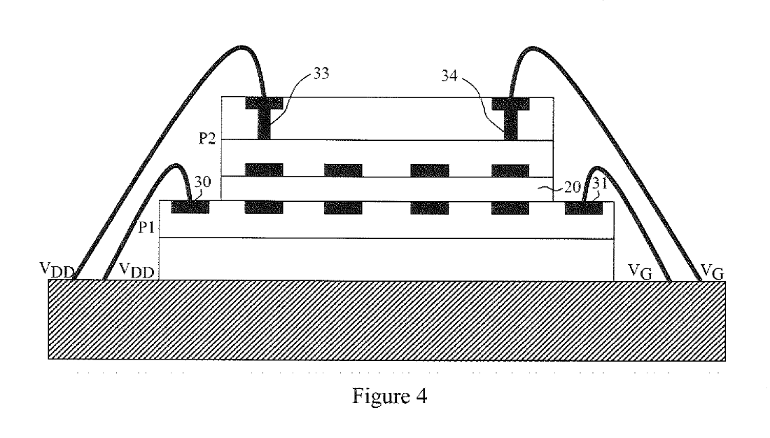

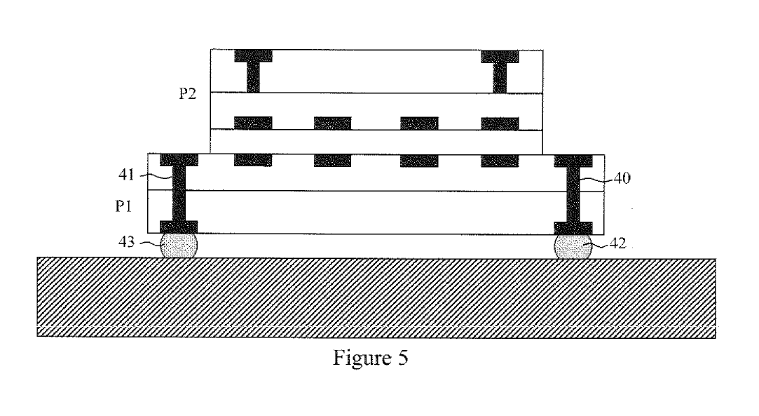

To establish the electric voltages between the chip pads during the breakdown period, an arrangement such as that in FIG. 4 or in FIG. 5 may for example be adopted.

In the case of the structure of FIG. 4, the lower chip or wafer juts out from the upper chip or wafer. End pads 30 and 31 of the lower chip are connected to high and low power supply terminals VDD and VG, respectively. On the upper chip side, through-silicon vias (or TSV) 33, 34 enable to establish contacts with the power supply terminals of the upper chip and these pads 33 and 34 are respectively connected to power supplies VDD and VG. Both chips being powered, it is possible by design to provide that, automatically, all buffers associated with the lower chip pads will set these pads to a first voltage, for example, VDD, and all buffers associated with the upper chip pads will set all these pads to a low voltage, for example, VG. Then, difference VDD-VG between pads will enable to break down the dielectric so that conductive metal can diffuse to provide the connections between the pads of the upper and lower chips.

According to a variation illustrated in FIG. 5, through vias 40 and 41, connected by respective balls 42 and 43 to power supply terminals, may also provide access to the lower chip pads. The lower and upper chips are then powered in the same way as described previously to obtain, between pads of these chips, voltages sufficient to create conductive areas between these pads as described previously.

Various embodiments with different variations have been described hereabove. It should be noted that those skilled in the art may combine various elements of these various embodiments and variations without showing any inventive step.

As a numerical example, each of the chips may comprise up to 1,000 opposite pads. The field to be applied to obtain the breakdown will be on the order of 1 MV/cm, that is, a voltage on the order of 1 V for a dielectric having a 100-nm thickness.

Such alterations, modifications, and improvements are intended to be part of this disclosure, and are intended to be Within the spirit and the scope of the present invention. Accordingly, the foregoing description is by way of example only and is not intended to be limiting. The present invention is limited only as defined in the following claims and the equivalents thereto.

What is claimed is:

1. A method for assembling a first semiconductor chip (P2) provided with pads (5B) on a second semiconductor chip or wafer (P1) provided with pads (5A), comprising:
covering the chip(s) with silicon oxide,
superposing the two chips, the pads being arranged substantially in front of one another, and
applying a voltage difference between the pads of the first and second chips to cause a breakdown of the dielectric and a diffusion of the conductor forming the pads into the broken down areas, whereby a conductive path forms between the opposite pads.

2 The method of claim 1, wherein the pads are made of copper.

3. A method as in claim 1 wherein the step of applying a voltage difference comprises:
applying the voltage difference for 1 to 10 milliseconds.
